(19) United States
(12) Patent Application Publication
(10) Pub. No.: US 2018/0138589 A1
(43) Pub. Date: May 17, 2018

(54) COMPOSITE METAMATERIAL, METHOD OF MANUFACTURE, AND USES THEREOF

(71) Applicant: ROGERS CORPORATION, Chandler, AZ (US)

(72) Inventors: Joseph S. Clegg, Providence, RI (US); Karl Edward Sprentall, Scottsdale, AZ (US); Aniruddha Shere, Chelmsford, MA (US)

(21) Appl. No.: 15/811,817

(22) Filed: Nov. 14, 2017

Related U.S. Application Data
(60) Provisional application No. 62/422,333, filed on Nov. 15, 2016.

(51) Int. Cl. H01Q 1/52; H05K 1/09; H01Q 1/36; H01Q 1/24; C08J 9/40; C08J 9/32; B32B 3/26; B32B 5/18; B32B 7/12; B32B 27/06; C08J 9/28

(52) U.S. Cl. CPC H01Q 1/523; C08J 2205/026; H01Q 1/364; H01Q 1/243; C08J 9/405; C08J 9/32; B32B 3/266; B32B 5/18; B32B 7/12; B32B 27/065; C08J 9/28; C08J 2300/00; C08J 2400/24; C08J 2400/22; B32B 2307/72; B32B 2307/204; B32B 2457/00; H05K 1/09

(57) ABSTRACT

Disclosed herein is a composite metamaterial comprising a polymer foam layer having one or both of a low dielectric constant of less than or equal to 2 and a low magnetic constant of less than or equal to 1, both determined at a frequency of 100 Hz and a temperature of 23° C.; wherein the polymer foam layer comprises a first surface, a second surface, and a plurality of vias that each independently at least partially extend from one or both of the first surface and the second surface into the polymer foam layer; and a via material having one or both of a high dielectric constant greater than the low dielectric constant and a high magnetic constant greater than the low magnetic constant disposed in and filling the plurality of vias.

### CROSS-REFERENCE TO RELATED APPLICATION

This application claims the benefit of U.S. Provisional Patent Application Ser. No. 62/422,333 filed Nov. 15, 2016. The related application is incorporated herein in its entirety by reference.

### BACKGROUND

The data rates and quality of service requirements for wireless communication systems have become comparable to those of wired communication systems. The theoretical performance gain achievable by such systems is limited based on a number of practical design factors, including the design of the antenna array and the amount of inter-array coupling. While coupling can be alleviated by increasing the spacing between array elements, accommodating multiple antennas with large spacing in modern consumer devices is increasingly difficult due to stringent space constraints. In order to meet such demanding, and often contradictory, design criteria, there remains a need in the art for improved materials that can facilitate the decoupling of neighboring antennas. Such a material could be useful in wireless communication systems as well as in many applications.

### BRIEF SUMMARY

Disclosed herein is a composite metamaterial comprising a polymer foam layer having one or both of a low dielectric constant of less than or equal to 2 and a low magnetic constant of less than or equal to 1, both determined at a frequency of 100 Hz and a temperature of 23° C.; wherein the polymer foam layer comprises a first surface, a second surface, and a plurality of vias that each independently at least partially extend from one or both of the first surface and the second surface into the polymer foam layer; and a via material having one or both of a high dielectric constant greater than the low dielectric constant and a high magnetic constant greater than the low magnetic constant disposed in and filling the plurality of vias.

Further disclosed is a method of manufacture of the composite metamaterial, comprising depositing the via material in the plurality of vias of the polymer foam layer; or comprising depositing the polymer foam layer and optionally foaming the polymer foam layer on a first substrate side of a substrate comprising a plurality of protrusions on the first substrate side; wherein the plurality of protrusions forms the plurality of vias.

Also disclosed herein are articles for the manufacture of antennas comprising the above-described metamaterials, and the antennas comprising the articles.

Further disclosed is a method of making the articles comprising metallizing one or both of the first surface and the second surface of the composite metamaterial to provide the article.

The above described and other features are exemplified by the following figures and detailed description.

### BRIEF DESCRIPTION OF THE DRAWINGS

The following Figures are exemplary embodiments, wherein the like elements are numbered alike.

FIG. 1 shows an embodiment of a composite metamaterial comprising cylindrical vias, where FIG. 1A is an embodiment of a cross-section taken at line 1A;

FIG. 2 shows a composite metamaterial comprising concentric vias;

FIG. 3 shows an embodiment of a composite metamaterial comprising curved planar vias; and

FIG. 4-7 show of embodiments of layered structures comprising the composite metamaterial.

### DETAILED DESCRIPTION

In the design of components comprising multiple antennas, the near fields of neighboring antennas can negatively affect the functioning of the antennas. The ability to decorrelate the signal of neighboring antennas can improve signal performance allowing for an increase in antenna packing, which can ultimately result in an increase in the number of users supported per unit of wireless infrastructure. In order to facilitate such a decorrelation, a composite metamaterial that can be used in an antenna was developed. The composite metamaterial comprises a polymer foam layer comprising a plurality of vias. As used herein the term foam refers to a material comprising a plurality of rounded voids, for example, spherical, oblong spherical, and the like. The polymer foam layer has one or both of a low dielectric constant, for example, of less than or equal to 2 and a low magnetic constant, for example, of less than or equal to 1. As used herein the dielectric constant and the magnetic constant can be determined at 23 degrees Celsius (° C.) and at a frequency of 100 Hertz (Hz). The plurality of vias can each independently at least partially extend from one or both of a first surface and a second surface of the polymer foam layer. The plurality of vias comprises a via material, wherein the via material has one or both of a high dielectric constant that is greater than the low dielectric constant of the polymer foam layer and a high magnetic constant that is greater than the low magnetic constant of the polymer foam layer.

The use of the polymer foam layer in the composite metamaterial is advantageous over a metamaterial using a solid low dielectric layer because the max ratio is increased when a foam is used. For example, in a metamaterial using a solid polymer layer such as a solid acrylonitrile-butadiene-styrene with a dielectric constant of 2.8 and a via material with a dielectric constant of 13, the max ratio would be about 4. In contrast, when a foam material with a dielectric constant, for example, of 1 or 1.1 and the same via material, the max ratio is beneficially increased to greater than 10. The presence of the polymer foam layer has the further benefit of being compressible and can allow for the composite metamaterial to easily conform to a shape of a device such as a smart phone.

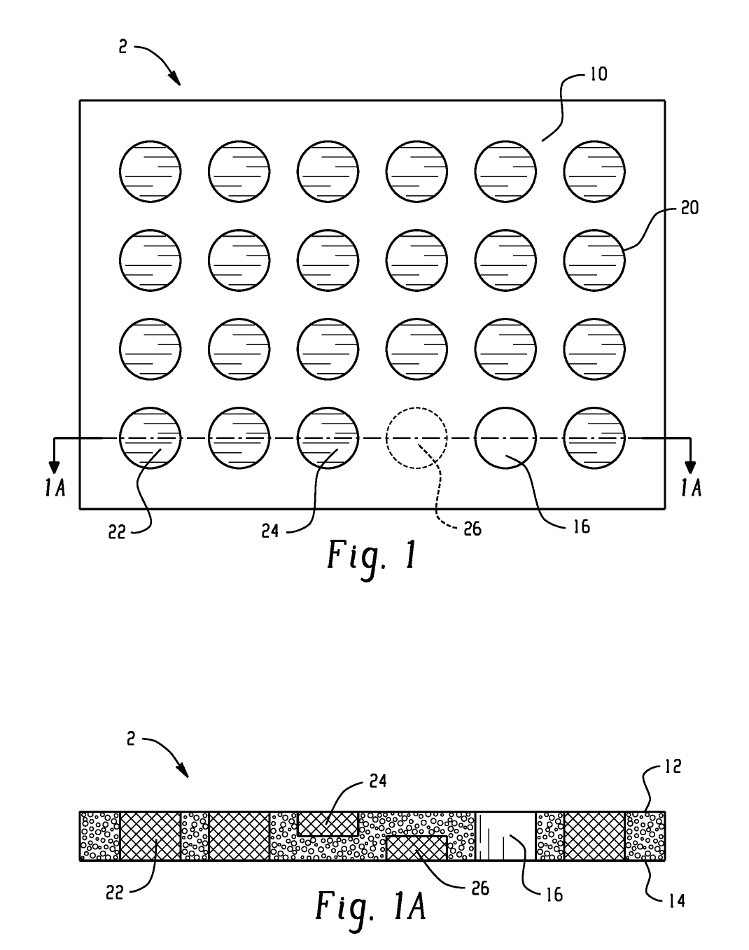

An example of a composite metamaterial is illustrated in FIG. 1, where the lower image is a cross-sectional image taken along line A. FIG. 1 illustrates that the composite metamaterial 2 comprises polymer foam layer 10 comprising first surface 12 and second surface 14. Polymer foam layer 10 comprises a plurality of cylindrical vias 20 that contain the via material.

The cylindrical vias can comprise one or both of through vias that connect the first surface and the second surface, providing a pathway there between and blind vias that only partially extend from one of the first and the second surface. For example, FIG. 1 illustrates through via 22 that connects first surface 12 and second surface 14, blind via 24 that extends only partially from first surface 12 into the polymer foam layer, and blind via 26 that extends only partially from second surface 14 into the polymer foam layer. The plurality of vias can consist of through vias that connect the first surface and the second surface.

The composite metamaterial can further comprise one or more hollow vias that are free of (i.e., do not contain) the via material. The hollow vias can each independently be a hollow, through via connecting the first surface to the second surface or can be a hollow, blind via. For example, FIG. 1 illustrates hollow, through via 16 that connects first surface 12 and second surface 14. One or more of the hollow vias can comprise a radiating element such as an antenna and/or a radio-frequency related component.

The vias can have a constant cross-section from the first surface to the second surface. The vias can have a regularly or an irregularly varying cross-section from the first surface to the second surface. For example, the size of the cross-section from the first surface to the second surface can increase from small to large from the first surface to the second surface either as a straight line or in steps. In other embodiments, the sidewalls of the vias can be substantially perpendicular to one or both of the first surface and the second surface of the polymer foam layer. As used herein, substantially perpendicular means that a central axis of the via can be within 10 degrees, or within 5 degrees of the perpendicular axis from one or both of the first surface and the second surface of the polymer foam layer.

The vias can have cross-section that is irregular or regular, for example circular, oval, square, triangular, rectangular, pentagonal, hexagonal, and the like, or a combination comprising at least one of the foregoing. The vias can have an average diameter of 0.1 to 5 millimeters (mm), or 0.1 to 2 mm. If the via is not cylindrical, then the diameter can be determined by calculating an average cross-sectional area of the via and determining a diameter of a circle with the same cross-sectional area.

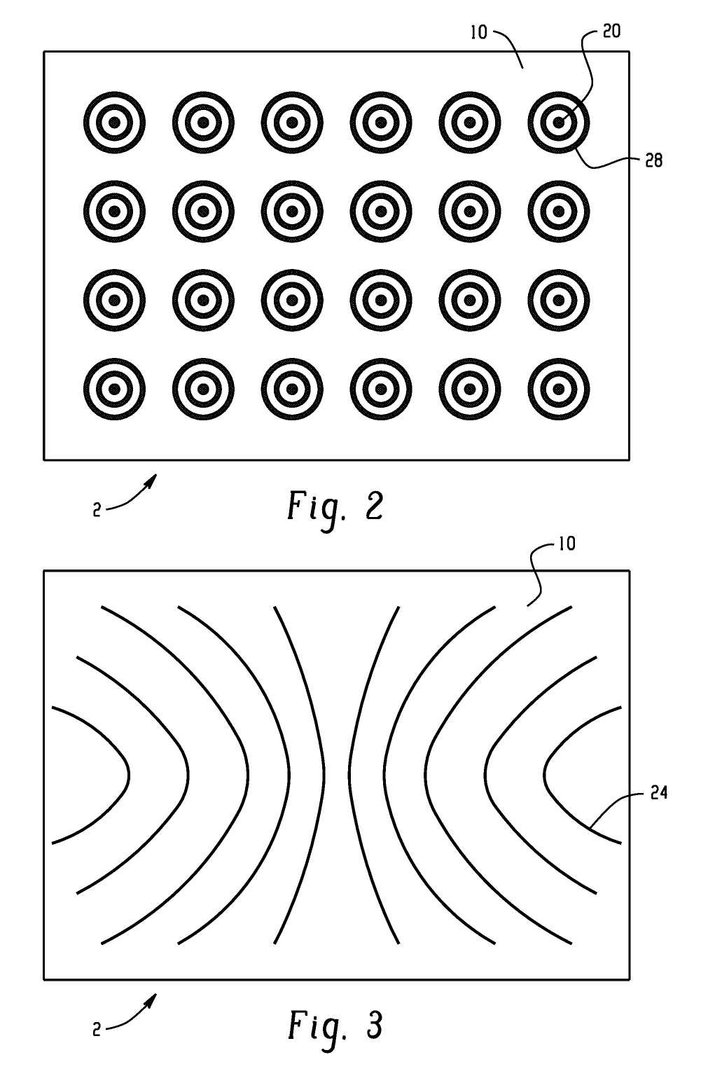

The vias can comprise a thin walled section, for example, to provide concentric vias, curved planar vias, and the like. FIG. 2 is an illustration of composite metamaterial comprising concentric cylindrical vias 28 concentrically located around cylindrical via 20 and FIG. 3 is an illustration of a composite metamaterial comprising curved planar vias 24.

The composite metamaterial can comprise a plurality of vias such as 2 to 1 million vias depending on the application or forming method. For example, if the composite metamaterial is formed via a roll manufacturing method, then the number of vias in the composite metamaterial would be a function of the length of the material prepared. The vias can be approximately equidistant from each other. The vias can be disposed in a grid array, for example, the vias can be hexagonally packed or can be packed in a square array.

The specific design of the vias can be determined by inputting an existing near field pattern; inputting a desired near field pattern; and applying a transform to transform the existing pattern to the desired pattern through the selection and structuring of the via material and the polymer foam material. Applying the transform can comprise using Maxwell's equations to derive a set of material properties and using linear algebra to define a plurality of desired vectors and, based on this information, determining the placement and location of via material in the composite metamaterial. The applying the transform can be an iterative process based on one or both of computational results and actual test results. Such a technique is described in “Spatially-Variant Periodic Structures in Electromagnetics,” Phil. Trans. R. Soc. A, Vol. 373, 2014.0359, July 2015, which is incorporated herein in its entirety.

The composite metamaterial can have an average thickness of 0.1 to 2,000 mm Depending on the application, the composite metamaterial can have a compression set of 1 to 10%, or 1 to 5%. The compression set can be determined in accordance with ASTM D 1667-90 or ASTM D 3574-95. The composite metamaterial can have a compression force deflection of 6 to 140 kilopascals (kPa), or 13 to 90 kPa. The compression force deflection can be determined in accordance with ASTM D 1667-90 or ASTM D 3574-95.

The polymer foam layer has one or both of a low dielectric constant, for example, of less than or equal to 2, or less than or equal to 1; and a low magnetic constant, for example, less than or equal to 1, or less than or equal to 0.5. The polymer foam layer can be open-cell, closed-cell, or a combination comprising at least one of the foregoing. The foam layer can be, for example, formed by one or more of mechanical frothing, a chemical blowing agent, or a physical foaming agent. The polymer foam layer can be a syntactic foam layer. A syntactic foam refers to a solid material that is filled with hollow particles, in particular spheres. The hollow particles can be, for example, ceramic, polymeric, glass (such as those made of an alkali borosilicate glass), or a combination comprising at least one of the foregoing. The syntactic foam can comprise 1 to 70 volume percent (vol %), or 5 to 70 vol %, or 10 to 50 vol % of the hollow particles based on the total volume of the polymer foam layer. The hollow particles can have a mean diameter of less than or equal to 300 micrometers, or 15 to 200 micrometers, or 20 to 70 micrometers. Compared to other types of foams, syntactic foams can have one or more of a better mechanical stability, a better coefficient of thermal expansion matching with the via material, or a reduced moisture absorption.

The polymer foam layer can comprise an aerogel. The aerogel can be organic or inorganic, and can comprise, for example, a polyurea, a polyurethane, a resorcinol-formaldehyde polymer, a polyisocyanate, an epoxy resin, carbon, a metal oxide, a metalloid oxide, boron nitride, graphene, silica, vanadia, or a combination comprising at least one of the foregoing. The aerogel can be produced by extracting the liquid component of a gel through, for example, supercritical drying. The aerogel can have one or more of a compressive yield strength of greater than or equal to 0.1 megapascal (MPa) and a compressive modulus of greater than or equal to 1 MPa as determined in accordance with ASTM D1621-16.

The polymer foam layer can comprise a thermoplastic or a thermoset polymer. The polymer foam layer can comprise a polyacetal, a poly(C₁₋₆ alkyl)acrylate, a polyacrylic, a polyamide, a polyamideimide, a polyanhydride, a polyarylate, a polyarylene ether, a polyarylene sulfide, a polybenzoxazole, a polycarbonate, a polyester (such as an alkyd), a polyetheretherketone, a polyetherimide, a polyetherketoneketone, a polyetherketone, a polyethersulfone, a polyimide (such as a polyetherimide), a poly(C₁₋₆ alkyl)methacrylate, a methacrylic polymer, a polyphthalide, a polyolefin (such as a fluorinated polyolefin), a polysilazane, a polysiloxane, a polystyrene, a polysulfide, a polysulfonamide, a polysulfonate, a polythioester, a polytriazine, a polyurea, a polyvinyl alcohol, a polyvinyl ester, a polyvinyl ether, a polyvinyl halide, a polyvinyl ketone, a polyvinylidene fluoride, an epoxy resin, a phenolic resin, a polyurethane, a silicone, or a combination comprising at least one of the foregoing.

In some embodiments the polymer foam layer comprises a polyolefin. The polyolefin can be a homopolymer such as polyethylene (such as low density polyethylene and high density polyethylene), polypropylene, or an alpha-olefin polymer (such as a C₃₋₁₀ alpha-olefin polymer), or a copolymer comprising ethylene, propylene, or C₃₋₁₀ alpha-olefin units, or a partially or fully halogenated analog of any of the foregoing, or a combination comprising at least one of the foregoing. The polyolefin can comprise a low density polyethylene (LDPE) having a melt flow index of 1 to 40 and a density of 0.91 to 0.93 grams per centimeter cubed (g/cc).

The polymer foam layer can comprise a fluoropolymer. “Fluoropolymer” as used herein include homopolymers and copolymers that comprise repeat units derived from a fluorinated alpha-olefin monomer, i.e., an alpha-olefin monomer that includes at least one fluorine atom substituent, and optionally, a non-fluorinated, ethylenically unsaturated monomer reactive with the fluorinated alpha-olefin monomer. Exemplary fluorinated alpha-olefin monomers include CF₂═CF₂, CHF═CF₂, CH₂═CF₂, CHCl═CHF, CClF═CF₂, CCl₂═CF₂, CClF═CClF, CHF═CCl₂, CH₂═CClF, CCl₂═CClF, CF₃CF═CF₂, CF₃CF═CHF, CF₃CH═CF₂, CF₃CH═CH₂, CHF₂CH═CHF, and CF₃CH═CH₂, and perfluoro(C₂₋₈ alkyl)vinylethers such as perfluoromethyl vinyl ether, perfluoropropyl vinyl ether, and perfluorooctylvinyl ether. The fluorinated alpha-olefin monomer can comprise tetrafluoroethylene (CF₂═CF₂), chlorotrifluoroethylene (CClF═CF₂), (perfluorobutyl)ethylene, vinylidene fluoride (CH₂═CF₂), hexafluoropropylene (CF₂═CFCF₃), or a combination comprising at least one of the foregoing. Exemplary non-fluorinated monoethylenically unsaturated monomers include ethylene, propylene, butene, and ethylenically unsaturated aromatic monomers such as styrene and alpha-methyl-styrene. Exemplary fluoropolymers include poly(chlorotrifluoroethylene) (PCTFE), poly(chlorotrifluoroethylene-propylene), poly(ethylene-tetrafluoroethylene) (ETFE), poly(ethylene-chlorotrifluoroethylene) (ECTFE), poly(hexafluoropropylene), polytetrafluoroethylene (PTFE), poly(tetrafluoroethylene-ethylene-propylene), poly(tetrafluoroethylene-hexafluoropropylene) (also known as fluorinated ethylene-propylene copolymer (FEP)), poly(tetrafluoroethylene-propylene) (also known as fluoroelastomer) (FEBPM), poly(tetrafluoroethylene-perfluoropropylene vinyl ether), a copolymer having a tetrafluoroethylene backbone with a fully fluorinated alkoxy side chain (also known as a perfluoroalkoxy polymer (PFA)) (for example, poly(tetrafluoroethylene-perfluoroproplyene vinyl ether)), polyvinylfluoride (PVF), polyvinylidene fluoride (PVDF), poly(vinylidene fluoride-chlorotrifluoroethylene), perfluoropolyether, perfluorosulfonic acid, and perfluoropolyoxetane, preferably perfluoroalkoxy alkane polymer, fluorinated ethylene-propylene, more preferably perfluoroalkoxy alkane polymer, or a combination comprising at least one of the foregoing. The polymer foam layer can comprise polytetrafluoroethylene.

In a specific embodiment, the polymer foam layer can comprise a polyurethane. The polymer foam layer can comprise a polyurethane foam such as PORON CONDUX PLUS™, which is commercially available from Rogers Corporation, Rogers, Conn.; or a silicone foam. The polyurethane can be formed by curing a prepolymer composition comprising an organic isocyanate component, a polyol, a catalyst, and optionally a surfactant. The prepolymer composition can comprise a polyurethane prepolymer formed by pre-reacting the organic polyisocyanate component with the polyol. The organic isocyanate components used in the preparation of polyurethane foams can comprise a polyisocyanate having the general formula Q(NCO)ᵢ, wherein i is an integer having an average value of greater than two, and Q is an organic radical having a valence of i. Q can be a substituted or unsubstituted hydrocarbon group (e.g., an alkane or an aromatic group of the appropriate valency). Q can be a group having the formula Q¹-Z-Q¹ wherein Q¹ is an alkylene or arylene group and Z is —O—, —O-Q¹-S, —CO—, —S—, —S-Q¹-S—, —SO— or —SO₂—. Exemplary isocyanates include hexamethylene diisocyanate, 1,8-diisocyanato-p-methane, xylyl diisocyanate, diisocyanatocyclohexane, phenylene diisocyanates, tolylene diisocyanates (including 2,4-tolylene diisocyanate, 2,6-tolylene diisocyanate, and crude tolylene diisocyanate), bis(4-isocyanatophenyl)methane, chlorophenylene diisocyanates, diphenylmethane-4,4′-diisocyanate (also known as 4,4′-diphenyl methane diisocyanate, or MDI) and adducts thereof, naphthalene-1,5-diisocyanate, triphenylmethane-4,4′,4″-triisocyanate, isopropylbenzene-alpha-4-diisocyanate, polymeric isocyanates such as polymethylene polyphenylisocyanate, and combinations comprising at least one of the foregoing isocyanates.

Q can also represent a polyurethane group having a valence of i, in which case Q(NCO)ᵢ is a composition known as a prepolymer. Such prepolymers can be formed by reacting a stoichiometric excess of a polyisocyanate with an active hydrogen-containing, for example, a polyhydroxyl-containing material or polyol. The polyisocyanate can be used in proportions of 30 to 200 percent stoichiometric excess, the stoichiometry being based upon equivalents of isocyanate group per equivalent of hydroxyl in the polyol.

The polyol can comprise one or both of a polyether polyol and a polyester polyol. Exemplary polyester polyols are inclusive of polycondensation products of polyols with dicarboxylic acids or ester-forming derivatives thereof (such as anhydrides, esters, and halides), polylactone polyols obtainable by ring-opening polymerization of lactones in the presence of polyols, polycarbonate polyols obtainable by reaction of carbonate diesters with polyols, and castor oil polyols. Exemplary dicarboxylic acids and derivatives of dicarboxylic acids that are useful for producing polycondensation polyester polyols are aliphatic or cycloaliphatic dicarboxylic acids such as glutaric, adipic, sebacic, fumaric, and maleic acids; dimeric acids; aromatic dicarboxylic acids such as phthalic, isophthalic, and terephthalic acids; tribasic or higher functional polycarboxylic acids such as pyromellitic acid; as well as anhydrides and second alkyl esters, such as maleic anhydride, phthalic anhydride, and dimethyl terephthalate.

Additional polyols are the polymers of cyclic esters. Exemplary cyclic ester monomers include δ-valerolactone; ε-caprolactone; zeta-enantholactone; and the monoalkyl-valerolactones (e.g., the monomethyl-, monoethyl-, and monohexyl-valerolactones). The polyester polyol can comprise caprolactone based polyester polyols, aromatic polyester polyols, ethylene glycol adipate based polyols, and combinations comprising at least one of the foregoing, and especially polyester polyols made from ε-caprolactones, adipic acid, phthalic anhydride, terephthalic acid and/or dimethyl esters of terephthalic acid.

A useful class of polyether polyols is represented generally by the following formula: R[(OCHₙH₂ₙ)_{z}OH]ₐ wherein R is hydrogen or a polyvalent hydrocarbon radical; a is an integer equal to the valence of R, n in each occurrence is an integer of 2 to 4 inclusive (for example, 3), and z in each occurrence is an integer having a value of 2 to 200, or 15 to 100. The polyether polyol can comprise a mixture of one or more of dipropylene glycol, 1,4-butanediol, and 2-methyl-1,3-propanediol, and the like.

The polyol can comprise a polyhydroxyl-containing compound (such as hydroxyl-terminated polyhydrocarbons and hydroxyl-terminated polyformals); a fatty acid triglyceride; a hydroxyl-terminated polyester; a hydroxymethyl-terminated perfluoromethylene; a hydroxyl-terminated polyalkylene ether glycol; a hydroxyl-terminated polyalkylenearylene ether glycol; a hydroxyl-terminated polyalkylene ether triol, or a combination comprising at least one of the foregoing.

The polyol can comprise a repeat unit derived from propylene oxide, tetrahydrofuran subjected to ring-opening polymerization, or a combination comprising at least one of the foregoing. The polyol can comprise less than or equal to 20 mol % of a repeat unit derived from ethylene oxide.

The polyols can have a hydroxyl number of 28 to 1,000, or 100 to 800. The hydroxyl number is defined as the number of milligrams of potassium hydroxide required for the complete neutralization of the hydrolysis product of the fully acetylated derivative prepared from 1 gram of polyol or mixtures of polyols with or without other cross-linking additives. The hydroxyl number, OH, can also be defined by the equation:

$$OH = \frac{56.1 \times 1000 \times f}{Mw}$$

wherein f is the average functionality as defined by the average number of hydroxyl groups per molecule of polyol, and M_{w} is the weight average molecular weight of the polyol based on polystyrene or polycarbonate standards.

The catalyst for use in polymerizing the polyurethane can comprise a phosphine; a tertiary organic amine; an organic salt; an inorganic acid salts, and/or an organometallic derivatives of one or more of: bismuth, lead, tin, iron, antimony, uranium, cadmium, cobalt, thorium, aluminum, mercury, zinc, nickel, cerium, molybdenum, vanadium, copper, manganese, and zirconium; or a combination comprising at least one of the foregoing. Specific examples of such catalysts include dibutyltin dilaurate, dibutyltin diacetate, stannous octoate, lead octoate, cobalt naphthenate, triethylamine, triethylenediamine, N,N,N′,N′-tetramethylethylenediamine, 1,1,3,3-tetramethylguanidine, N,N,N′N′-tetramethyl-1,3-butanediamine, N,N-dimethylethanolamine, N,N-diethylethanolamine, 1,3,5-tris (N,N-dimethylaminopropyl)-s-hexahydrotriazine, o- and p-(dimethylaminomethyl) phenols, 2,4,6-tris(dimethylaminomethyl) phenol, N,N-dimethylcyclohexylamine, pentamethyldiethylenetriamine, 1,4-diazobicyclo [2.2.2] octane, N-hydroxyl-alkyl quaternary ammonium carboxylates and tetramethylammonium formate, tetramethylammonium acetate, tetramethylammonium 2-ethylhexanoate, and so forth, as well as combinations comprising at least one of the foregoing catalysts. The catalyst can comprise ferric acetylacetonate (FeAA), for example, when the blowing agent comprises water, where the water can react with the isocyanate thereby releasing CO₂. Other catalysts or adjuvants, e.g., amines, can be used to adjust the relative reaction rates of water and urethane. The catalyst can be present in an amount of 0.03 to 3 weight percent (wt %), based on the total weight of the polyol.

In other embodiments, the polymer foam layer can comprise a silicone polymer. Silicone prepolymer compositions can include, based on the total weight of the composition: 100 parts by weight of a vinyl silicone; 0.05 to 10 parts by weight of a silicon hydride-containing crosslinker; and 0.2 to 10 parts by weight of catalyst. The viscosity of the prepolymer compositions before cure can be 10,000 to 500,000 millipascal seconds (mPa·sec) at 25° C.

The vinyl silicone is siloxane having one or more vinyl groups or substituted vinyl group bonded to a silicon atom. As used herein, a vinyl group is a group having the formula —CH═CH₂, and a substituted vinyl group has the formula —CH═CR₂, where the R groups can be independently hydrogen or C₁₋₆ alkyl groups. The vinyl silicone can comprise a polydialkyl siloxane having more than one vinyl group or substituted vinyl group bonded to silicon. Specifically, the vinyl silicone includes a polydiorganosiloxane functionalized with a terminal —Si (R¹R²)—CH═CH₂ group, wherein R¹ and R² are each independently hydrogen or C₁₋₆ alkyl groups, for example, a dimethylvinyl-terminated dimethylsiloxane of the formula —Si(Me)₂-CH═CH₂. A vinyl group or substituted vinyl group can be present at one or both termini of the vinyl silicone. Alternatively, or in addition, the vinyl or substituted vinyl group can be bonded to a non-terminal silicon atom of the vinyl silicone.

The vinyl silicone can comprise a vinyl silicone of Formula (I)

R^{B}[Si(R¹R²)—O]—[(Si(R³R⁴)—O)]ₙ—[Si(R⁵R⁶)—O)]ₘ—Si(R¹R²)—R^{A} (I)

wherein n has an average value of 1 to 200, or 50 to 150; m is 0 or has an average value of 1 to 20,000, or 10,000 to 20,000; R^{A}, R^{B}, R¹, R², R³, R⁴, R⁵ and R⁶ are each independently phenyl or C₁₋₆ alkyl; and at least one of R^{A}, R^{B}, R³ or R⁴ has the formula —CH═CR^{F}R^{G}, where R^{F} and R^{G} are each independently hydrogen or C₁₋₆ alkyl. In Formula (I), the R^{A}, R^{B}, R¹, R², R³, R⁴, R⁵, and R⁶ groups that are not vinyl can be an alkyl group such as methyl, ethyl, or propyl. A viscosity of the vinyl silicone can be 10,000 to 500,000 mPa·sec at 25° C.

The silicon hydride-containing crosslinker includes one or more groups containing a hydrogen atom bonded to a silicon atom (—SiH). The silicone hydride-containing crosslinker can comprise a compound comprising silicon-bonded hydride groups at one or more terminal ends thereof. Alternatively, or in addition, one or more silicon-bonded hydride groups can be present along the backbone of the crosslinker. The silicone hydride-containing crosslinker can also include two or more silicon-bonded hydrogen atoms, or three or more silicon-bonded hydrogen atoms. The silicone hydride-containing crosslinker can comprise two or three silicon-bonded hydrogen atoms, and up to eight silicon-bonded hydrogen atoms per molecule.

The silicone hydride-containing crosslinker can comprise a silicone hydride-containing crosslinker of Formula (II)

R^{D}—Si(R⁷R⁸)O—)[Si(R⁹R¹⁰—O)]ₓ—[Si(R¹¹R¹²)—O]_{y}—Si(R¹³R¹⁴)—R_{E} (II)

wherein at least one of R^{D}, R^{E}, R⁷, R⁸, R⁹, R¹⁰, R¹¹, R¹², R¹³ and R¹⁴ is hydrogen; and the others of R^{D}, R^{E}, R⁷, R⁸, R⁹, R¹⁰, R¹¹, R¹², R¹³ and R¹⁴ are each independently phenyl or C₁₋₆ alkyl; x has an average value of 1 to 300, or 100 to 300; y is 0 or has an average value of 1 to 300, or 100 to 300. Both of R^{D} and R^{E} can be hydrogen and R⁷, R⁸, R⁹, R¹⁰, R¹¹, R¹², R¹³, and R¹⁴ can each independently be phenyl or methyl. The silicone hydride-containing crosslinker can have a hydride content of 0.02 to 10 weight percent and a viscosity of 10 to 10,000 centipoise at 25° C.

The catalyst for silicone polymer formation can comprise a platinum-containing catalyst. The platinum-containing catalyst can comprise a Pt(0) complex, a Pt(II) complex, a Pt(IV) complex, or a combination comprising at least one of the foregoing. The platinum-containing catalyst can comprise bis-(1,3-divinyl-1,1,3,3-tetramethyldisiloxane) platinum (0); (2,4,6,8-tetramethyl-2,4,6,8-tetravinylcyclotetrasiloxane) platinum(0); ethylenebis(triphenylphosphine)platinum(0), bis(tri-tert-butylphosphine) platinum(0); tetrakis(triphenylphosphine) platinum(0); dimethyl (1,5-cyclooctadiene)platinum(II); trans-dichlorobis(triethylphosphine) platinum(II); dichlorobis(ethylenediamine) platinum(II); dichloro(1,5-cyclooctadiene) platinum(II); platinum(II) chloride; platinum(II) bromide; platinum(II) iodide; trans-platinum(II)diamine dichloride; dichloro(1,2-diaminocyclohexane) platinum(II); and ammonium tetrachloroplatinate(II); dihydrogen hexachloroplatinate (IV) hexahydrate; platinum(IV) oxide hydrate; ammonium hexachloroplatinate(IV), or a combination comprising at least one of the foregoing.

The catalyst for silicone polymer formation can comprise a peroxide catalyst, for example an inorganic or organic peroxide (such as an aliphatic, aromatic, or mixed aliphatic-aromatic peroxide), or a combination comprising at least one of the foregoing. For example, the peroxide catalyst can include benzoyl peroxide, di-t butyl peroxide, 2,4-dichlorobenzoyl peroxide, or 2,5-bis(t-butylperoxy)-2,5-dimethylhexane.

The polymer foam layer can be formed by, for example, forming a layer comprising a polymer; and foaming the layer. Forming the layer can comprise casting the polymer or a curable prepolymer composition onto a surface. Foaming the layer can comprise mechanical frothing the composition before forming the layer, using of a blowing agent (either chemical or physical) during or after forming the layer, or a combination of frothing and blowing.

The polymer foam can be deposited selectively in an additive process utilizing any method of foaming the polymer. This additive process can be the same process or a different process step from the inclusion of the high constant material, which can be done additively or otherwise. For example, a thermoplastic polymer can be extruded with a blowing agent such that as the melt is extruded through a die at the end of the extruder, and thus into a region of reduced temperature and pressure, the reduction in pressure causes the blowing agent to nucleate and expand into a plurality of cells that solidify upon cooling, thereby trapping the blowing agent within the cells.

When the polymer foam layer comprises a thermoset, the polymer foam layer can be formed from a curable prepolymer composition, where the curable prepolymer composition can be partially or fully cured at one or more steps during formation of the polymer foam layer, for example, during formation of the layer, after the formation of the layer and prior to blowing, during blowing, and after blowing.

If a blowing agent is used, the blowing agent can comprise a physical blowing agent, a chemical blowing agent, or a combination comprising at least one of the foregoing. Examples of physical blowing agents include a hydrocarbon (for example, a C₁₋₆ hydrocarbon including a linear C₁₋₆ alkane, a branched C₁₋₆ alkane, a cyclic C₁₋₆ alkane, an ether, or an ester), a partially halogenated hydrocarbon such as a linear, branched, or cyclic C₁₋₆ fluoroalkane, nitrogen, oxygen, argon, carbon dioxide, or a combination comprising at least one of the foregoing. Specific physical blowing agents include a chlorofluorocarbons (for example, 1,1-dichloro-1-fluoroethane, 1,1-dichloro-2,2,2-trifluoro-ethane, monochlorodifluoromethane, and 1-chloro-1,1-difluoroethane); a fluorocarbon (for example, 1,1,1,3,3,3-hexafluoropropane, 2,2,4,4-tetrafluorobutane, 1,1,1,3,3,3-hexafluoro-2-methylpropane, 1,1,1,3,3-pentafluoropropane, 1,1,1,2,2-pentafluoropropane, 1,1,1,2,3-pentafluoropropane, 1,1,2,3,3-pentafluoropropane, 1,1,2,2,3-pentafluoropropane, 1,1,1,3,3,4-hexafluorobutane, 1,1,1,3,3-pentafluorobutane, 1,1,1,4,4,4-hexafluorobutane, 1,1,1,4,4-pentafluorobutane, 1,1,2,2,3,3-hexafluoropropane, 1,1,1,2,3,3-hexafluoropropane, 1,1-difluoroethane, 1,1,1,2-tetrafluoroethane, and pentafluoroethane); a fluoroether (for example, methyl-1,1,1-trifluoroethylether and difluoromethyl-1,1,1-trifluoroethylether; hydrocarbons such as n-pentane, isopentane, and cyclopentane); or a combination comprising at least one of the foregoing.

Examples of chemical blowing agents that can be used include those that decompose to form gas. The chemical blowing agent can comprise water, azoisobutyronitrile, azodicarbonamide (i.e., azo-bis-formamide), barium azodicarboxylate, substituted hydrazines (e.g., diphenylsulfone-3,3′-disulfohydrazide, 4,4′-hydroxy-bis-(benzenesulfohydrazide), trihydrazinotriazine, and aryl-bis-(sulfohydrazide)), semicarbazides (e.g., p-tolylene sulfonyl semicarbazide an d4,4′-hydroxy-bis-(benzenesulfonyl semicarbazide)), triazoles (e.g., 5-morpholyl-1,2,3,4-thiatriazole), N-nitroso compounds (e.g., N,N′-dinitrosopentamethylene tetramine and N,N-dimethyl-N,N′-dinitrosophthalmide), benzoxazines (e.g., isatoic anhydride), or a combination comprising at least one of the foregoing.

The amount of blowing agent incorporated into the polymer or prepolymer composition is an amount effective to provide the resultant foam the desired bulk density. For example, the blowing agent can be used in an amount of 0.1 to 50 wt %, or 10 to 30 wt %, or 0.1 to 10 wt % based on the total weight of the composition. The blowing agent can be incorporated, for example, by diffusion into the polymer or prepolymer composition. Diffusing the blowing agent can occur after forming the layer.

The polymer foam layer can comprise one or more other components or additives, such as a nucleating agent (such as zinc oxide, titanium dioxide, zirconium oxide, silica, talc, and the like), a dispersing aid, an adhesion promoter, a colorant, a plasticizer, a heat stabilizer (such as carbon black, calcium carbonate, and metal oxides (such as iron oxide and zinc oxide)), an antioxidants, or the like, or a combination comprising at least one of the foregoing. The polymer foam layer can comprise a reinforcing material, for example, that can increase its dimensional stability. The reinforcing material can comprise a glass cloth. The glass cloth can be woven or non-woven. The polymer foam layer can be foamed in the presence of the reinforcing material such that the polymer foam layer penetrates the interstitial areas of the reinforcing material.

After forming the polymer foam layer, the polymer foam layer comprises a plurality of cells that can comprise one or both of open cells and closed cells. Depending upon the application, the closed cells can have an average cell diameter of 1 to 200 μm, or 1 to 100 μm.

The polymer foam layer can have a density of 16 to 400 kilograms per meter cubed (kg/m³), or 90 to 300 kg/m³. The density can be determined in accordance with ASTM D 3574-95, Test A. The polymer foam layer can have an average cell diameter of 10 to 800 micrometers, or 20 to 500 micrometers. The polymer foam layer can have a compression set of 1 to 10%, or 1 to 5%. The polymer foam layer can be flexible or rigid. The polymer foam layer can have a compression force deflection of 6 to 140 kPa, or 13 to 90 kPa. The polymer foam layer can have a void volume content of 20 to 99 volume percent (vol %), or 30 to 99 vol %, based upon the total volume of the polymer foam layer.

The via material disposed in the plurality of vias has one or both of a high dielectric constant that is greater than the low dielectric constant of the polymer foam layer and a high magnetic constant that is greater than the low magnetic constant of the polymer foam layer. The high dielectric constant can be greater than 2, or 3 to 100, or greater than or equal to 10, or 10 to 100 at a frequency of 100 Hz and a temperature of 23° C. The high magnetic constant can be greater than 1, or 1.1 to 100, or greater than or equal to 10, or 10 to 100 at a frequency of 100 Hz and a temperature of 23° C. The via material can be an unfoamed, solid material, for example, a polymer. Each of the vias can contain the same or different via material. For example, a first portion of the vias can comprise a first via material and a second portion of the vias can comprise a second via material different from the first dielectric material. The first via material can have the same or different dielectric constant as the second via material.

The via material can comprise a thermoplastic or a thermoset polymer. The via material can comprise a polyacetal, a poly(C₁₋₆ alkyl)acrylate, a polyacrylic, a polyamide, a polyamideimide, a polyanhydride, a polyarylate, a polyarylene ether, a polyarylene sulfide, a polybenzoxazole, a polycarbonate, a polyester (such as an alkyd), a polyetheretherketone, a polyetherimide, a polyetherketoneketone, a polyetherketone, a polyethersulfone, a polyimide, a poly(C₁₋₆alkyl)methacrylate, a methacrylic polymer, a polyolefin (such as a fluorinated polyolefin, polyethylene, polypropylene), a polyphthalide, a polysilazane, a polysiloxane, a polystyrene, a polysulfide, a polysulfonamide, a polysulfonate, a polythioester, a polytriazine, a polyurea, a polyurethane, a polyvinyl alcohol, a polyvinyl ester, a polyvinyl ether, a polyvinyl halide, a polyvinyl ketone, a polyvinylidene fluoride, an epoxy resin, a phenolic resin, a polydiallyl phthalate, a polyurethane, a silicone polymer, or a combination comprising at least one of the foregoing. The via material can comprise a polycarbonate, a polyolefin, a silicone polymer, or a combination comprising at least one of the foregoing. The via material can comprise a polycarbonate. The via material can comprise a polyolefin. The via material can comprise a silicone.

The via material can comprise a particulate filler. The particulate filler can comprise a ceramic, a glass, or a combination comprising at least one of the foregoing. The particulate filler can comprise titanium dioxide (TiO₂), barium titanate (BaTiO₃), Ba₂Ti₉O₂₀, strontium titanate, silica, corundum, wollastonite, solid glass spheres, hollow glass spheres, ceramic hollow spheres, quartz, boron nitride, aluminum nitride, silicon carbide, beryllia, alumina, alumina trihydrate, magnesia, mica, talc, a nanoclay, magnesium hydroxide, or a combination comprising at least one of the foregoing.

The polymer foam layer can comprise a thermoset and the via material can comprise a thermoplastic. The via material can comprise a thermoset and the polymer foam layer can comprise a thermoplastic.

The polymer foam layer and the via material can be bonded together, for example, by van der Waals forces, covalent bonds, or through an adhesive material can be located in between the polymer foam layer and the via material. For example, if one or both of the polymer foam layer and the via material comprises a thermoplastic material, then the composite metamaterial can be increased to a temperature at or above the glass transition temperature of the thermoplastic material to allow for the formation of an interconnected boundary between the polymer foam layer and the vias. Alternatively, if one or both of the polymer foam layer and the via material comprises a thermoset material, then the thermoset material can be partially cured prior to the introduction of the second material and then fully cured to result in an interconnected boundary between the thermoset material and the second material.

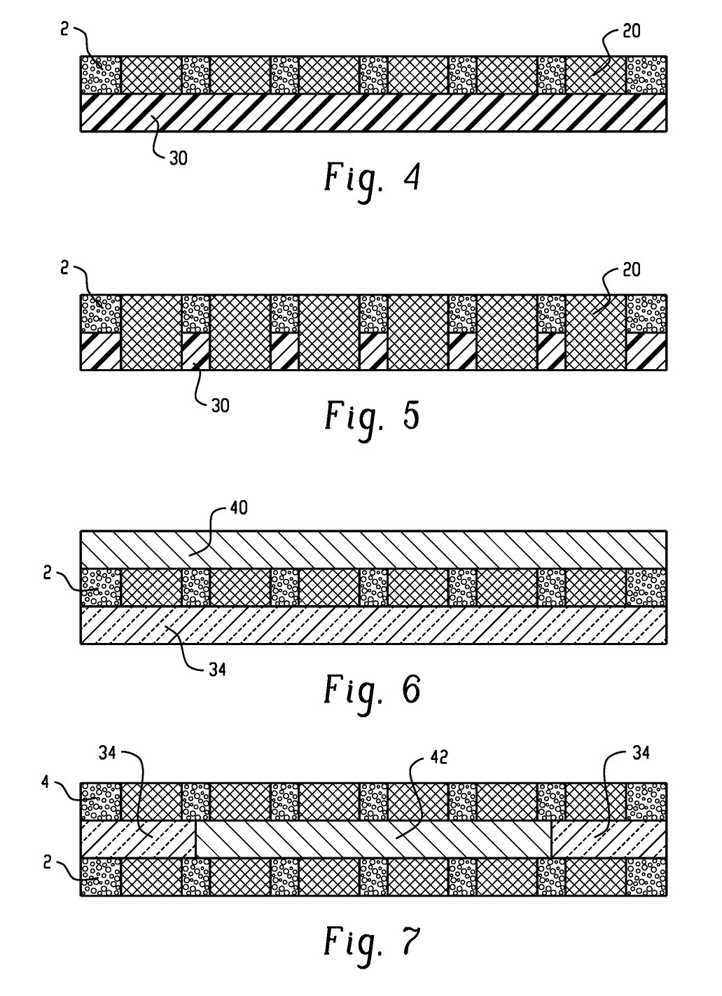

FIG. 4-7 are illustrations of embodiments of a layered structure comprising a composite metamaterial layer. The layered structure can comprise adhesive layer 34 (such as a pressure sensitive adhesive layer), support layer 30 (that can act to provide mechanical support to the composite metamaterial), conductive layer 40, second metamaterial layer 4, or a combination comprising at least one of the foregoing. The plurality of vias can extend through one or more of the additional layers in the composite metamaterial layer and can optionally comprise the via material. For example, 0 to 100% of the plurality of vias can extend through the support layer 30. FIG. 4 and FIG. 6 illustrate an embodiment where 0% of cylindrical vias 20 extend through support layer 30, adhesive layer 34, or antenna layer 40 and FIG. 5 illustrates an embodiment where 100% of cylindrical vias 20 extend through support layer 30.

The layered structure can comprise an adhesive layer. The adhesive layer can be located on one or both of the first surface and the second surface of the composite metamaterial layer. The adhesive layer can be located on an outer surface of the layered structure. The adhesive layer can comprise a pressure sensitive adhesive. The adhesive layer can be used to adhere the composite metamaterial to a further layer, such as a support layer or to an article comprising the composite metamaterial. For example, FIG. 6 is an illustration of a layered structure comprising adhesive layer 34.

A support layer 30 can be located on one or both of the first surface and the second surface of the composite metamaterial. A support layer can be located on an outer surface of the layered structure. For example, FIG. 4 and FIG. 5 are illustrations of composite metamaterial 2 located on substrate 30. The support layer can be removable from the composite metamaterial or can be bonded, for example, via an adhesive layer located between the composite metamaterial and the support layer. The support layer can encapsulate the composite metamaterial. When a support layer is present, an adhesive layer, such as a pressure sensitive adhesive layer, can be located on an outer surface of the support layer.

The support layer can comprise a polymer layer such as a polyester (such as polyethylene terephthalate), a polycarbonate, a polyacetal, a polyamide, a polyolefin (such as a fluorinated polyolefin), a silicone, or a combination comprising at least one of the foregoing. The support layer can comprise polyethylene terephthalate. The support layer can comprise a polyimide such as KAPTON™ commercially available from DuPont. The support layer can have a thickness of less than or equal to 25 micrometers, or 10 to 20 micrometers, or 10 to 15 micrometers. In some embodiments, the foam layer is cast or extruded directly on to the support layer.

Conductive layer 40 can be located on one or both sides of the layered structure. The conductive layer can comprise copper, silver, stainless steel, gold, aluminum, zinc, tin, lead, transition metals, or a combination comprising at least one of the foregoing. The conductive layer can be printed on a surface of the layered structure, for example, on first surface 12 of composite metamaterial layer 2. The conductive layer can be printed by a direct metallization process such as mask sputtering, ink jet printing, vapor deposition, and screen printing. The conductive layer can comprise continuous conductive layer 40, for example, as illustrated in FIG. 6. Conversely, the conductive layer can comprise discontinuous conductive layer, for example, for use in an antenna or to form a circuit. Forming the conductive layer and the composite metamaterial can be performed in a continuous process. The conductive layer can be located on a support layer, where the support layer metallized, for example, by laser directed structuring.

There are no particular limitations regarding the thickness of the conductive layer, nor are there any limitations as to the shape, size, or texture of the surface of the conductive layer. The conductive layer can have a thickness of 3 to 200 micrometers, for example, 9 to 180 micrometers. When two or more conductive layers are present, the thickness of the two layers can be the same or different. In an exemplary embodiment, the conductive layer is a copper layer. Suitable conductive layers include a thin layer of a conductive metal such as a copper foil presently used in the formation of circuits, for example, electrodeposited copper foils. The copper foil can have a route mean squared (RMS) roughness of less than or equal to 2 micrometers, for example, less than or equal to 0.7 micrometers, where roughness is measured using a Veeco Instruments WYCO Optical Profiler, using the method of white light interferometry.

The conductive layer can be applied by a variety of methods, for example, by printing, electrodeposition, chemical vapor deposition, lamination, molding, adhesion, or the like. In an embodiment, the conductive layer is place in a mold prior to molding. For example, a laminated substrate can comprise an optional polyfluorocarbon layer that can be located in between the conductive layer and the composite metamaterial, and a layer of microglass reinforced fluorocarbon polymer that can be located in between the polyfluorocarbon layer and the conductive layer. The layer of microglass reinforced fluorocarbon polymer can increase the adhesion of the conductive layer to the composite metamaterial. The microglass can be present in an amount of 4 to 30 wt % based on the total weight of the layer. The microglass can have a longest length scale of less than or equal to 900 micrometers, or less than or equal to 500 micrometers. The microglass can be microglass of the type as commercially available by Johns-Manville Corporation of Denver, Colo. The polyfluorocarbon layer comprises a fluoropolymer (such as polytetrafluoroethylene (PTFE), a fluorinated ethylene-propylene copolymer (such as Teflon FEP), and a copolymer having a tetrafluoroethylene backbone with a fully fluorinated alkoxy side chain (such as Teflon PFA)).

The conductive layer can be applied by adhesively applying the conductive layer. In an embodiment, the conductive layer is the circuit (the conductive layer of another circuit), for example, a flex circuit. For example, an adhesion layer can be disposed between the conductive layers and the composite metamaterial. The adhesion layer can comprise a poly(arylene ether); and a carboxy-functionalized polybutadiene or polyisoprene polymer comprising butadiene, isoprene, or butadiene and isoprene units, and zero to less than or equal to 50 wt % of co-curable monomer units; wherein the composition of the adhesive layer is not the same as the composition of the substrate layer. The adhesive layer can be present in an amount of 2 to 15 grams per square meter. The poly(arylene ether) can comprise a carboxy-functionalized poly(arylene ether).

The layered structure can comprise a second metamaterial layer. The first and second metamaterial layers can be adhesively bonded together or ultrasonically welded together. The adhesive and the ultrasonic welding bond the entire surface area of the two metamaterial layers together or a portion of the surface area of the two surfaces together. For example, an edge portion of the surface area of the two layers can be joined. FIG. 7 is an illustration of a layered structure comprising composite metamaterial layer 2 and second metamaterial layer 4. Discontinuous conductive layer 42 (for example, comprising an antenna) can be located in between composite metamaterial layer 2 and second metamaterial layer 4 and adhesive layer 34 can be located in an edge portion of the surface area in between the two metamaterial layers. An adhesive layer can be located in between the conductive layer and the composite metamaterial. For example, the adhesive layer can comprise a poly(arylene ether) that can provide increased bond strength of the composite metamaterial to the conductive layer.

The composite metamaterial can comprise a surface feature. For example, the composite metamaterial can comprise a concave feature such as a skiving, a hole, or a dimple. The concave feature can be present to accommodate a protruding component in an article comprising the composite metamaterial. The composite metamaterial can comprise a convex feature or other protrusion of any shape to fit into a complementary feature of another component.

The composite metamaterial can be prepared by a variety of methods. In some methods, the polymer foam layer is formed, vias are introduced into the foam layer, and then the vias are filled with the via material. In other methods, the polymer foam layer containing vias is formed, and the vias are filled; or the polymer foam layer and filled vias can be manufactured in a single operation.

For example, the foam layer can be prepared by forming the polymer foam layer, optionally on a removable substrate or on a support layer. The foam can be perforated, for example by punching, die-cutting, laser cutting, or a combination comprising at least one of the foregoing. The perforating can comprise bringing a portion of a polymer foam layer in contact with a punch. In other embodiments, the perforating can comprise rolling the polymer foam sheet in contact in a punching machine, for example, comprising a roller punch (such as a rotating cylinder comprising a plurality of surface features that can punch the plurality of vias in the polymer foam layer.

The filling the plurality of vias can comprise filling a first portion (or all) of the plurality of vias with the via material, for example, by masking the polymer foam layer to leave first portion of the plurality of vias exposed before depositing the via material. The filling of the plurality of vias can comprise filling with a thermosetting via material, for example, by reaction injection molding; and curing the thermosetting via material. Prior to curing the thermosetting via material, an excess thermosetting material located above first surface of the polymer foam layer can be removed, for example, by a sponge roller or a squeegee.

The filling of the plurality of vias in a polymer foam layer with a via material can comprise filling the plurality of vias with a melted thermoplastic via material, for example, by injection molding; and cooling the melted thermoplastic via material. Prior to cooling the thermoplastic via material, an excess thermoplastic material located above first surface of the polymer foam layer can be removed, for example, by a sponge roller or a squeegee.

In another embodiment, the polymer foam layer and the vias can be formed at the same time, for example in a mold. After the polymer foam layer is removed from the mold, the vias can be filled as described above.

In still another embodiment, the composite metamaterial can be prepared by foaming a polymer foam layer on a first substrate side of a substrate comprising a plurality of protrusions; wherein the plurality protrusions forms the plurality of vias through the polymer foam layer. In addition to a first plurality of protrusions, the substrate can comprise a second plurality of protrusions comprising a material different from the via material of the first protrusions.

The substrate comprising the plurality protrusions can be unitary, that is, the substrate material and the protrusion can comprise the same via material. This substrate can be formed by molding the single substrate material in a mold comprising a plurality of surface features. The molding can comprise injection molding a thermoplastic polymer or reaction injection molding a thermosetting polymer. Alternatively, forming the unitary substrate material can comprise forming a block, mass, or layer of the unitary substrate material, then forming the plurality of surface features, for example, by etching using a block mask or by stamping.

In still other embodiments, the substrate can be a multi-material substrate, where the plurality of protrusions comprises the via material and the substrate comprises a second material different from the via material. The multi-material substrate can be formed by molding a via material in a plurality of surface features in a mold and molding a substrate material, in any order, such that a surface of the via material is in contact with a surface of the substrate material. For example, the multi-material substrate can be formed by molding a via material in the plurality of surface features in a mold; bringing a surface of a substrate comprising the second material into contact with a surface of the plurality of surface features; wherein an adhesive layer can be located in between the surface of the plurality of surface features and the surface of the substrate and/or a weld layer can be formed (for example, by heating or ultrasonic welding) to weld the plurality of surface features to the substrate. The molding can comprise injection molding a thermoplastic polymer or reaction injection molding a thermosetting polymer. The multi-material substrate can be formed by 3D printing the plurality of protrusions on the substrate.

In any of the foregoing methods, if one or both of the first surface and the second surface is an uneven surface, for example, if a thickness the polymer foam layer is greater than or equal to height, h, of the protrusions or if the height of the protrusions is greater than a thickness of the polymer foam layer, then the process can further comprise planarizing the uneven surface. The planarizing can comprise abrading the uneven surface. The planarizing can comprise using a solvent to remove an excess material on the uneven surface, for example, using a sponge roller.

After the composite metamaterial is prepared, the composite metamaterial can be cut to a desired size, for example, by die cutting. A conductive layer can be added, for example, by a masked sputtering, before or after cutting the metamaterial.

The composite metamaterial can comprise one or more (or two or more) embedded radiating elements (such as an antenna). For example, the one or more embedded radiating elements can be located in one or more hollow vias. The composite metamaterial can help to reduce the correlation between two or more embedded radiating elements. The composite metamaterial can be in close proximity to one or more (or two or more) radiating elements (such as an antenna). As used herein, close proximity means that the radiating elements is close enough to the composite metamaterial that the composite metamaterial can reduce a correlation between the radiating element and a second radiating element. For example, the one or more radiating element can be located on a surface of the composite metamaterial.

Two or more composite metamaterial can be layered on top of one another to form a layered composite metamaterial. The multiple layers can be in direct contact with each other or can comprise intervening layers such as conductive layers, antenna layers, and adhesive layers.

The composite metamaterial can be used in a circuit material. The composite metamaterial can be used in an antenna such as an inverted antenna or a planar inverted antenna. The composite metamaterial can be used in a mobile internet device such as a smart phone, an internet watch, or a tablet.

Set forth below are various non-limiting embodiments of the composite metamaterial, methods of making, and articles made therefrom.

### Embodiment 1

A composite metamaterial, comprising: a polymer foam layer having one or both of a low dielectric constant of less than or equal to 2 and a low magnetic constant of less than or equal to 1, both determined at a frequency of 100 Hz and a temperature of 23° C.; wherein the polymer foam layer comprises a first surface, a second surface, and a plurality of vias that each independently at least partially extend from one or both of the first surface and the second surface into the polymer foam layer; and a via material having one or both of a high dielectric constant greater than the low dielectric constant and a high magnetic constant greater than the low magnetic constant disposed in and filling the plurality of vias.

### Embodiment 2

The composite metamaterial of any one or more of the preceding embodiments, wherein the polymer foam layer has a density of 16 to 400 kg/m³.

### Embodiment 3

The composite metamaterial of any one or more of the preceding embodiments, wherein the polymer foam layer comprises a polyacrylate, a polyacrylic, a polyamide, a polyamideimide, a polyanhydride, a polyarylate, a polyarylene ether, a polyarylene sulfide, a polybenzoxazole, a polycarbonate, a polyester, a polyetheretherketone, a polyetherimide, a polyetherketoneketone, a polyetherketone, a polyethersulfone, a polyimide, a polymethacrylate, a methacrylic polymer, a polyolefin, a polyphthalide, a polysilazane, a polysiloxane, a polystyrene, a polysulfide, a polysulfonamide, a polysulfonate, a polythioester, a polytriazine, a polyurea, a polyurethane, a polyvinyl alcohol, a polyvinyl ester, a polyvinyl ether, a polyvinyl halide, a polyvinyl ketone, a polyvinylidene fluoride, an epoxy resin, a phenolic resin, a polyurethane, a silicone, or a combination comprising at least one of the foregoing.

### Embodiment 4

The composite metamaterial of any one or more of the preceding embodiments, wherein the plurality of vias have an average diameter of 0.1 to 5 mm, or 0.1 to 2 mm.

### Embodiment 5

The composite metamaterial of any one or more of the preceding embodiments, wherein the plurality of vias are cylindrical in shape and substantially perpendicular to one or both of the first surface and the second surface.

### Embodiment 6

The composite metamaterial of any one or more of the preceding embodiments, wherein the plurality of vias are approximately equidistant from one another, and optionally, wherein the plurality of vias are disposed in a grid array.

### Embodiment 7

The composite metamaterial of any one or more of the preceding embodiments, wherein the via material comprises a polyacetal, polyacrylate, polyacrylic, polyamide, polyamideimide, polyanhydride, polyarylate, polyarylene ether, polyarylene sulfide, polybenzoxazole, polycarbonate, polyester, polyetheretherketone, polyetherimide, polyetherketoneketone, polyetherketone, polyethersulfone, polyimide, polymethacrylate, methacrylic polymer, polyolefin, fluorinated polyolefin, polyphthalide, polysilazane, polysiloxane, polystyrene, polysulfide, polysulfonamide, polysulfonate, polythioester, polytriazine, polyurea, polyurethane, polyvinyl alcohol, polyvinyl ester, polyvinyl ether, polyvinyl halide, polyvinyl ketone, polyvinylidene fluoride, alkyd, epoxy resin, phenolic resin, polydiallyl phthalates, polyurethane, silicone, or a combination comprising at least one of the foregoing.

### Embodiment 8

The composite metamaterial of any one or more of the preceding embodiments, wherein the via material is a solid.

### Embodiment 9

The composite metamaterial of any one or more of the preceding embodiments, wherein the via material comprises a particulate filler.

### Embodiment 10

The composite metamaterial of embodiment 9, wherein the particulate filler comprises a ceramic or a glass, preferably, particulate filler can comprise titanium dioxide, barium titanate, strontium titanate, silica, corundum, wollastonite, Ba₂Ti₉O₂₀, solid glass spheres, hollow glass spheres, ceramic hollow spheres, quartz, boron nitride, aluminum nitride, silicon carbide, beryllia, alumina, alumina trihydrate, magnesia, mica, talc, nanoclays, magnesium hydroxide, or a combination comprising at least one of the foregoing.

### Embodiment 11

The composite metamaterial of any one or more of the preceding embodiments, wherein the plurality of vias comprises a first portion of the vias and a second portion of the vias, where the first portion of the vias comprises a first via material and the second portion of the vias comprises a second material different from the first via material.

### Embodiment 12

The composite metamaterial of any one or more of the preceding embodiments, wherein the composite metamaterial has an average thickness of 0.1 to 25 millimeters.

### Embodiment 13

The composite metamaterial of any one or more of the preceding embodiments, wherein the polymer foam layer and the via material are bonded.

### Embodiment 14

The composite metamaterial of any one or more of the preceding embodiments, wherein the polymer foam layer comprises a thermoplastic and the via material comprises a thermoset.

### Embodiment 15

The composite metamaterial of any one or more embodiments 1 to 13, wherein the polymer foam layer comprises a thermoset and the via material comprises a thermoplastic.

### Embodiment 16

The composite metamaterial of any one or more of the preceding embodiments, further comprising an adhesive layer, a support layer, a conductive layer, a second metamaterial layer, or a combination comprising at least one of the foregoing, each independently disposed on one or both of the first surface and the second surface.

### Embodiment 17

The composite metamaterial of embodiment 16, further comprising the conductive layer disposed on the first surface.

### Embodiment 18

The composite metamaterial of any one or more of the preceding embodiments, further comprising a surface feature located on one or both of the first surface and the second surface.

### Embodiment 19

The composite metamaterial of any one or more of the preceding embodiments, wherein the plurality of vias comprises a plurality of through vias extending from the first surface to the second surface.

### Embodiment 20

The composite metamaterial of any one or more of the preceding embodiments, wherein the plurality of vias comprises a plurality of blind vias, each independently only partially extending from one of the first surface and the second surface.

### Embodiment 21

The composite metamaterial of any one or more of the preceding embodiments, further comprising one or more hollow vias at least partially extending from the first surface to the second surface; wherein the one or more hollow vias each independently optionally comprises a radiating element.

### Embodiment 22

The composite metamaterial of any one or more of the preceding embodiments, wherein the polymer foam layer comprises a reinforcing material.

### Embodiment 23

The composite metamaterial of any one or more of the preceding embodiments, wherein the polymer foam layer comprises an aerogel.

### Embodiment 24

The composite metamaterial of any one or more of the preceding embodiments, wherein the polymer foam layer comprises a syntactic foam comprising a plurality of hollow spheres.

### Embodiment 25

A method for the manufacture of the composite metamaterial of any one or more of the preceding embodiments, comprising: depositing the via material in the plurality of vias of the polymer foam layer.

### Embodiment 26

The method of embodiment 25, comprising manufacturing the composite metamaterial in a continuous, roll-to-roll process.

### Embodiment 27

The method of embodiment 25 or embodiment 26, further comprising masking the polymer foam layer to leave at least a fraction of the plurality of vias exposed before depositing the via material.

### Embodiment 28

The method of any one or more of embodiments 25 to 27, wherein the depositing comprises placing a thermosetting via material in the plurality of vias; and curing the thermosetting via material, for example, by reaction injection molding.

### Embodiment 29

The method of any one or more of embodiments 25 to 27, wherein the depositing comprises placing a melted thermoplastic via material in the plurality of vias; and cooling the melted thermoplastic via material, for example, by injection molding.

### Embodiment 30

The method of any one or more of embodiments 25 to 29, further comprising perforating the polymer foam layer to provide the plurality of vias.

### Embodiment 31

The method of embodiment 30, wherein the perforating comprises punching, die-cutting, laser cutting, or a combination comprising at least one of the foregoing.

### Embodiment 32

The method of any one or more of embodiments 25 to 31, further comprising forming the polymer foam layer with the plurality of vias, or forming the polymer foam layer and then perforating the polymer foam layer.

### Embodiment 33

The method of embodiment 32, further comprising forming the polymer foam layer on a support layer, wherein the support layer is optionally removable.

### Embodiment 34

A method for the manufacture of the composite metamaterial of any one or more of embodiments 1 to 24, comprising depositing the polymer foam layer and optionally foaming the polymer foam layer on a first substrate side of a substrate comprising a plurality of protrusions on the first substrate side; wherein the plurality of protrusions forms the plurality of vias.

### Embodiment 35

The method of embodiment 34, wherein the protrusions and the substrate comprise the via material.

### Embodiment 36

The method of embodiment 34, wherein the plurality of protrusions comprise the via material and the substrate comprises a second material different from the via material.

### Embodiment 37

The method of embodiment 36, wherein an adhesive is located in between the via material of the plurality of protrusions and the second material of the substrate; or wherein the via material of the plurality of protrusions and the second material of the substrate are welded together.

### Embodiment 38

The method of any one or more of embodiments 36 to 37, wherein the second material is removable from the via material.

### Embodiment 39

The method of any one or more of embodiments 25 to 38, further comprising planarizing an uneven surface of the composite metamaterial.

### Embodiment 40

An article comprising the composite metamaterial of any one or more of embodiments to 1 to 24, or the composite metamaterial made by the method of any one or more of embodiments 25 to 39.

### Embodiment 41

The article of embodiment 40, wherein the article is an antenna.

### Embodiment 42

The article of embodiment 40 or embodiment 41, wherein the article is an antenna, and wherein the low dielectric constant, the high dielectric constant, a number of vias in the plurality of vias, and a via spacing are effective to achieve a pre-selected near field pattern in order to decorrelate a signal from an adjacent antenna element.

### Embodiment 43

The article of embodiment 40, wherein the article is a circuit material.

### Embodiment 44

The article of embodiment 40, wherein the article is a component of a mobile internet device.

### Embodiment 45

A method for the manufacture of the articles of any one or more of embodiments 40 to 44, the method comprising metallizing one or both of the first surface and the second surface of the composite metamaterial to provide the article.

### Embodiment 46

The method of embodiment 45, wherein the metallizing provides a continuous conductive layer on the surface.

### Embodiment 47

The method of embodiment 45, wherein the metallizing provides a discontinuous conductive layer, preferably, in the form of a circuit or an antenna.

### Embodiment 48

The method of any one or more of embodiments 45 to 47, comprising forming the composite metamaterial and metallizing the surface in a continuous process.

In general, the compositions, methods, and articles can alternatively comprise, consist of, or consist essentially of, any ingredients, steps, or components herein disclosed. The compositions, methods, and articles can additionally, or alternatively, be formulated, conducted, or manufactured so as to be devoid, or substantially free, of any ingredients, steps, or components not necessary to the achievement of the function or objectives of the present claims.

The endpoints of all ranges directed to the same component or property are inclusive of the endpoints, are independently combinable, and include all intermediate points. For example, a range of “up to 25 wt %, or 5 to 20 wt %” is inclusive of the endpoints and all intermediate values of the ranges of “5 to 25 wt %,” such as 10 to 23 wt %, etc.). “Combinations” is inclusive of blends, mixtures, alloys, reaction products, and the like. The terms “first,” “second,” and the like, do not denote any order, quantity, or importance, but rather are used to distinguish one element from another. The terms “a” and “an” do not denote a limitation of quantity, but rather denote the presence of at least one of the referenced item. “Or” means “and/or” unless clearly stated otherwise by context. “Optional” or “optionally” means that the subsequently described event or circumstance may or may not occur, and that the description includes instances where the event occurs and instances where it does not.

Reference throughout the specification to “an embodiment”, “another embodiment”, “some embodiments”, and so forth, means that a particular element (e.g., feature, structure, step, or characteristic) described in connection with the embodiment is included in at least one embodiment described herein, and may or may not be present in other embodiments. In addition, it is to be understood that the described elements may be combined in any suitable manner in the various embodiments.

Unless defined otherwise, technical and scientific terms used herein have the same meaning as is commonly understood by one of skill in the art to which this disclosure belongs. All cited patents, patent applications, and other references are incorporated herein by reference in their entirety. However, if a term in the present application contradicts or conflicts with a term in the incorporated reference, the term from the present application takes precedence over the conflicting term from the incorporated reference.

While particular embodiments have been described, alternatives, modifications, variations, improvements, and substantial equivalents that are or can be presently unforeseen can arise to applicants or others skilled in the art. Accordingly, the appended claims as filed and as they can be amended are intended to embrace all such alternatives, modifications variations, improvements, and substantial equivalents.

1. A composite metamaterial, comprising:
a polymer foam layer having one or both of a low dielectric constant of less than or equal to 2 or a low magnetic constant of less than or equal to 1, each determined at a frequency of 100 Hz and a temperature of 23° C.; wherein the polymer foam layer comprises a first surface, a second surface opposite the first surface, and a plurality of vias that each independently at least partially extend from one or both of the first surface and the second surface into the polymer foam layer; and
a via material having one or both of a high dielectric constant greater than the low dielectric constant and a high magnetic constant greater than the low magnetic constant disposed in and filling the plurality of vias.

2. The composite metamaterial of claim 1, wherein the polymer foam layer has a density of 16 to 400 kg/m³.

3. The composite metamaterial of claim 1, wherein the polymer foam layer comprises a poly(C₁₋₆ alkyl)acrylate, a polyacrylic, a polyamide, a polyamideimide, a polyanhydride, a polyarylate, a polyarylene ether, a polyarylene sulfide, a polybenzoxazole, a polycarbonate, a polyester, a polyetheretherketone, a polyetherimide, a polyetherketoneketone, a polyetherketone, a polyethersulfone, a polyimide, a poly(C₁₋₆ alkyl)methacrylate, a methacrylic polymer, a polyolefin, a polyphthalide, a polysilazane, a polysiloxane, a polystyrene, a polysulfide, a polysulfonamide, a polysulfonate, a polythioester, a polytriazine, a polyurea, a polyurethane, a polyvinyl alcohol, a polyvinyl ester, a polyvinyl ether, a polyvinyl halide, a polyvinyl ketone, a polyvinylidene fluoride, an epoxy resin, a phenolic resin, a polyurethane, a silicone, or a combination comprising at least one of the foregoing.

4. The composite metamaterial of claim 1, wherein the plurality of vias have an average diameter of 0.1 to 5 mm.

5. The composite metamaterial of claim 1, wherein the plurality of vias are cylindrical in shape and perpendicular to one or both of the first surface and the second surface.

6. The composite metamaterial of claim 1, wherein the via material comprises a polyacetal, poly(C₁₋₆ alkyl)acrylate, polyacrylic, polyamide, polyamideimide, polyanhydride, polyarylate, polyarylene ether, polyarylene sulfide, polybenzoxazole, polycarbonate, polyester, polyetheretherketone, polyetherimide, polyetherketoneketone, polyetherketone, polyethersulfone, polyimide, poly(C₁₋₆ alkyl)methacrylate, methacrylic polymer, polyolefin, fluorinated polyolefin, polyphthalide, polysilazane, polysiloxane, polystyrene, polysulfide, polysulfonamide, polysulfonate, polythioester, polytriazine, polyurea, polyurethane, polyvinyl alcohol, polyvinyl ester, polyvinyl ether, polyvinyl halide, polyvinyl ketone, polyvinylidene fluoride, alkyd, epoxy resin, phenolic resin, polydiallyl phthalate, polyurethane, silicone, or a combination comprising at least one of the foregoing.

7. The composite metamaterial of claim 1, wherein the via material is a solid.

8. The composite metamaterial of claim 1, wherein the via material comprises a particulate filler.

9. The composite metamaterial of claim 1, wherein the composite metamaterial has an average thickness of 0.1 to 25 millimeters.

10. The composite metamaterial of claim 1, further comprising an adhesive layer, a support layer, a conductive layer, a second metamaterial layer, or a combination comprising at least one of the foregoing, each independently disposed on one or both of the first surface and the second surface.

11. The composite metamaterial of claim 1, wherein the plurality of vias comprises one or both of a plurality of blind vias, each independently only partially extending from one of the first surface and the second surface; and one or more hollow vias at least partially extending from the first surface to the second surface, wherein the one or more hollow vias each independently optionally comprises a radiating element.

12. The composite metamaterial of claim 1, wherein the polymer foam layer comprises an aerogel.

13. The composite metamaterial of claim 1, wherein the polymer foam layer comprises a syntactic foam comprising a plurality of hollow spheres.

14. A method for the manufacture of the composite metamaterial of claim 1, comprising depositing the via material in the plurality of vias of the polymer foam layer.

15. The method of claim 14, comprising manufacturing the composite metamaterial in a continuous, roll-to-roll process.

16. The method of claim 14, wherein the depositing comprises placing a thermosetting via material in the plurality of vias; and curing the thermosetting via material; or wherein the depositing comprises placing a melted thermoplastic via material in the plurality of vias; and cooling the melted thermoplastic via material.

17. The method of claim 14, further comprising perforating the polymer foam layer before the depositing to provide the plurality of vias.

18. A method for the manufacture of the composite metamaterial of claim 1, comprising depositing the polymer foam layer and optionally foaming the polymer foam layer on a first substrate side of a substrate comprising a plurality of protrusions on the first substrate side; wherein the plurality of protrusions forms the plurality of vias.

19. An article comprising the composite metamaterial of claim 1.

20. The article of claim 20, wherein the article is an antenna or a circuit material.
